(19) United States
(12) Patent Application Publication
(10) Pub. No.: US 2011/0241058 A1
(43) Pub. Date: Oct. 6, 2011

(54) LED HEAT DISSIPATING MODULE

(76) Inventor: Yu-Chen CHIEN, Zhunan Township (TW)

(21) Appl. No.: 12/749,815

(22) Filed: Mar. 30, 2010

(51) Int. Cl. H01L 33/00

(52) U.S. Cl. 257/99; 257/E33.075

(57) ABSTRACT

A light emitting diode (LED) heat dissipating module includes an aluminum base plate, at least one connecting hole formed on aluminum base plate, and a copper pillar installed in the connecting hole, such that the bottom of the aluminum heat dissipating base plate of the LED is coupled to a distal surface of the copper pillar, and the heat produced by the aluminum heat dissipating base plate can be conducted to the aluminum base plate by a copper body to achieve a quick heat dissipating effect.

### BACKGROUND OF THE INVENTION

1. Field of the Invention

The present invention relates to a light emitting diode (LED) heat dissipating module, and more particularly to an LED heat dissipating module applied to illumination products and equipments for reducing the temperature of a high heat produced by the LED to achieve an expected heat dissipating performance.

2. Description of the Related Art

Light emitting diode (LED) has the advantages of a lower power consumption, a high brightness and a small volume, and becomes a component used extensively in various different illumination equipments such as a flash light and a light bulb, etc, and the LED even takes over the conventional tungsten bulb as a popular mainstream product of the small illumination equipments and a first choice of consumers.

Although LED has the advantages of the low power consumption and the high brightness, the LED with a high light emitting performance also produces a relatively high heat during its operation. If the heat is not dissipated or discharged during its operation, the normal operation of the LED and related circuits will be affected, and even the using life of the LED will be affected adversely.

To overcome the heat dissipating problem of the LED, related manufacturers used aluminum heat dissipating fins as the heat dissipating material for the LED, a copper base plate as a conducting interface between the LED and the heat dissipating fins, a hole groove formed on the copper base plate for installing the LED, and a plurality of embedding grooves formed at the bottom of the copper base plate for embedding and installing the heat dissipating fins, such that the LED and the heat dissipating fins are contacted with each other indirectly through the copper base plate, and the heat produced by the operation of the LED can be conducted to the heat dissipating fins copper base plate. With a large heat dissipating area of the heat dissipating fins and a good thermal conductivity of the aluminum, the high heat produced by the LED can be dissipated or discharged easily to reduce the risk of affecting the LED and related circuits, and extend the overall using life of the LED.

Although the design of the heat dissipating structure of this sort can achieve the expected heat dissipating performance, the way of using the heat dissipating fins as the heat dissipating material may accumulate hot air between adjacent heat dissipating fins, if the heat dissipating fins are densely arranged and no fan is available for providing a cooling air current. As a result, the hot air cannot be discharged effectively, and the heat dissipating structure does not help much to reducing the high heat produced by the LED. Since the heat dissipating fins have a relatively larger volume, its copper base plate must come with a large area before achieving a good conducting performance between the heat dissipating fins and the LED, but the large copper base plate incurs a higher cost, and the overall heat dissipating fins cannot improve the heat dissipating effect significantly.

In other words, present heat dissipating modes of the LED still require improvements on both cost and efficiency.

### SUMMARY OF THE INVENTION

In view of the foregoing shortcomings of the prior art, the inventor of the present invention based on years of experience in the related industry to conduct extensive researches and experiments, and finally developed a heat dissipating module for a light emitting diode in accordance with the present invention to overcome the shortcomings of the prior art.

It is a primary objective of the present invention to provide an LED heat dissipating module using an aluminum heat dissipating base plate together with a copper pillar to achieve the heat conduction and dissipation of the heat produced by the LED, and the installation configuration of the copper pillar and the aluminum heat dissipating base plate provides a larger contact area for the heat conduction to enhance the heat dissipating efficiency significantly.

Another objective of the present invention is to provide a structural design of an LED heat dissipating module capable of increasing the contact area between a copper pillar and an aluminum heat dissipating base to enhance the heat conduction efficiency without increasing the thickness of the aluminum heat dissipating base plate or the cost of the aluminum heat dissipating base plate.

To achieve the foregoing objective, the present invention provides an LED heat dissipating module with the following advantages and benefits:

The structural design of the present invention includes a connecting hole formed on the aluminum heat dissipating base plate for connecting and installing the copper pillar, and a flange formed at an upper rim, a lower rim or both rims of the connecting hole of the aluminum heat dissipating base plate for increasing the thickness, such that after the copper base plate and the aluminum heat dissipating base plate are coupled, a distal end of the copper pillar is in contact with a copper base plate of the LED, so that the high heat produced by the LED can be conducted from the copper pillar to the aluminum heat dissipating base plate quickly to reduce the high temperature quickly, due to the high thermal conductivity of the copper, the large contact area, and the high thermal conductivity of the aluminum. The invention enhances the heat dissipating performance of the LED significantly without increasing much material cost.

### BRIEF DESCRIPTION OF THE DRAWINGS

FIG. 1 is a schematic view of a structure of a first preferred embodiment of the present invention;

FIG. 2 is an exploded view of a structure of a first preferred embodiment of the present invention;

FIG. 3 is a schematic view of a structural relation of a first preferred embodiment of the present invention;

FIG. 4 is an exploded view of a structural relation of a second preferred embodiment of the present invention;

FIG. 5 is an exploded view of a structural relation of a third preferred embodiment of the present invention;

FIG. 6 is an exploded view of a structural relation of a fourth preferred embodiment of the present invention;

FIG. 7 is an exploded view of a structural relation of a fifth preferred embodiment of the present invention;

FIG. 8 is an exploded view of a structural relation of a sixth preferred embodiment of the present invention;

FIG. 9 is an exploded view of a structural relation of a seventh preferred embodiment of the present invention;

FIG. 10 is an exploded view of a structural relation of an eighth preferred embodiment of the present invention;

FIG. 11 is an exploded view of a structural relation of a ninth preferred embodiment of the present invention; and

FIG. 12 is an exploded view of a structural relation of a tenth preferred embodiment of the present invention.

### DETAILED DESCRIPTION OF THE PREFERRED EMBODIMENTS

The structural assembly, technical characteristics and effects of the present invention will become apparent with the detailed description of preferred embodiments and the illustration of related drawings as follows.

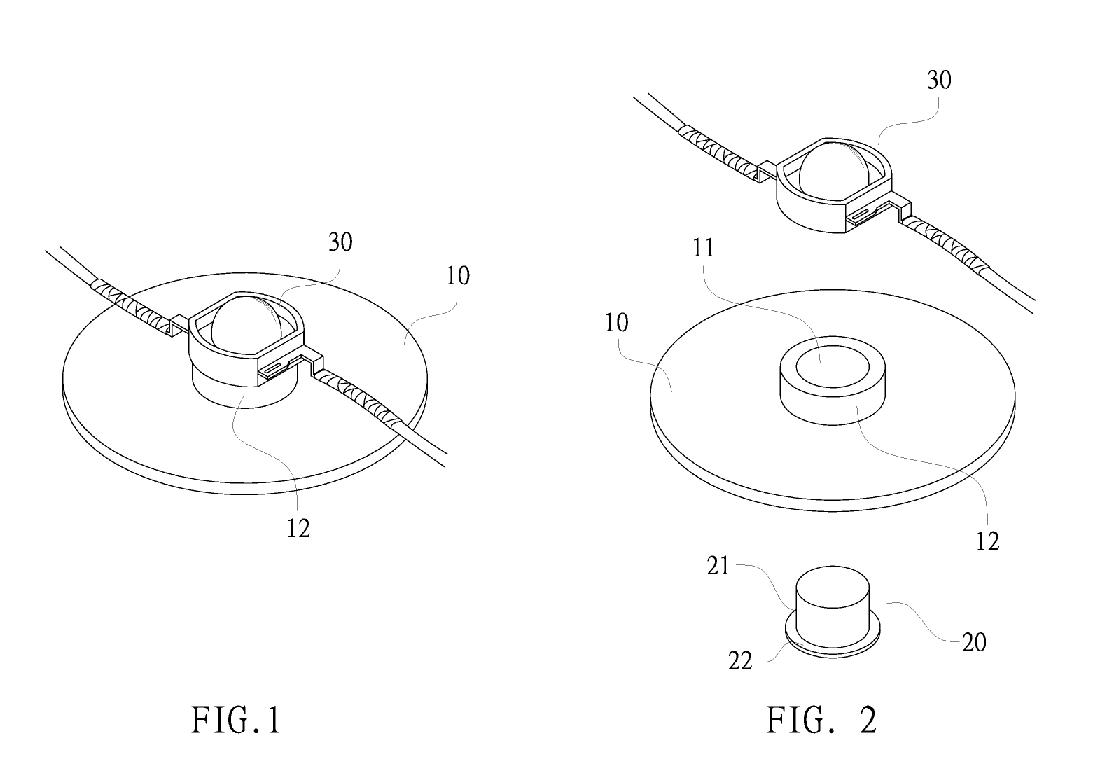

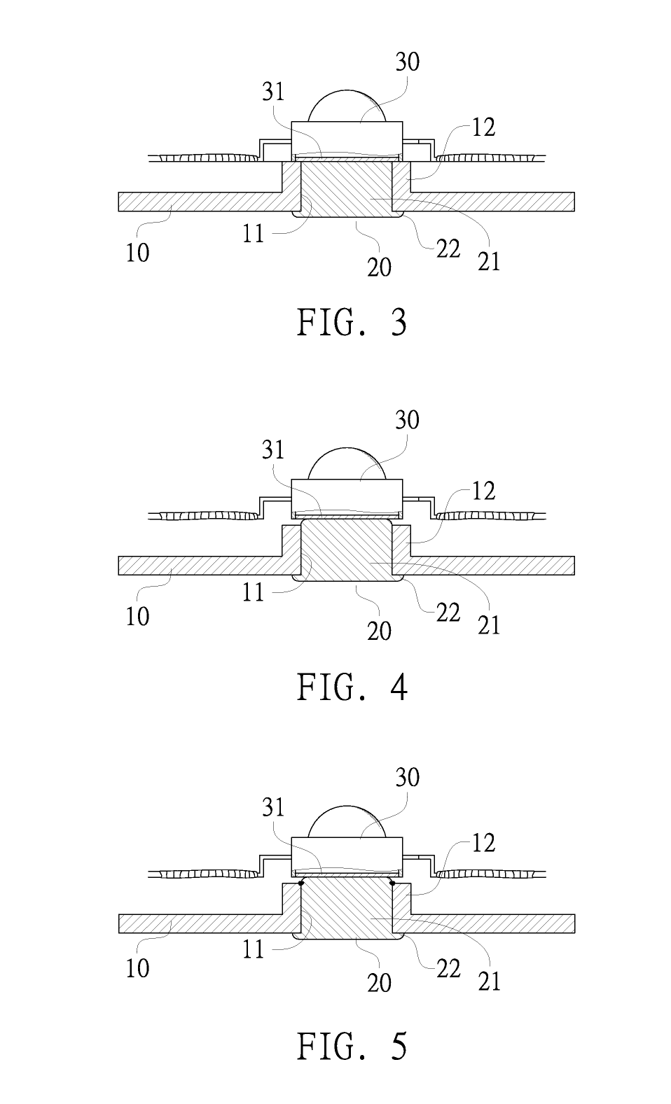

With reference to FIGS. 1 to 4 for a schematic view of a structure, an exploded view of the structure and a schematic view of a structural relation of a first preferred embodiment of the present invention, and a schematic view of a structural relation of a second preferred embodiment of the present invention respectively, a structural design of an LED heat dissipating module in accordance with the present invention includes an aluminum heat dissipating base plate 10 in a predetermined shape, and the aluminum heat dissipating base plate 10 is made according to the size and shape of the actual operation, and one or more connecting holes 11 are formed on the aluminum heat dissipating base plate 10 according to the actual number of installed light emitting diodes (LED), and a flange 12 is formed at a rim (a upper rim, a lower rim or both upper and lower rims) of the connecting hole 11 to increase the thickness and integrally extend to a predetermined height. The connecting holes 11 are provided for installing a copper pillar 20 by a punch riveting process, and a body 21 of the copper pillar 20 is engaged securely with the hole diameter of the connecting hole 11 of the aluminum heat dissipating base plate 10, wherein a head 22 of the copper pillar 20 is slightly greater than the hole diameter of the connecting hole 11, such that when the copper pillar 20 is installed into the connecting hole 11 of the aluminum heat dissipating base plate 10 by the punch riveting process to achieve the secured connection, so as to assure that the body 21 and the connecting hole 11 to be abutted against an internal wall of the flange 12, and the contact area will be greater than the thickness of the aluminum heat dissipating base plate 10 due to the flange 12. Therefore, the contact area provided for conducting heat of the copper pillar 20 and the aluminum heat dissipating base plate 10 can be increased effectively without increasing the thickness of the aluminum heat dissipating base plate 10. In addition, a distal surface of the copper pillar 20 is exposed and protruded from the flange 12, such that the contact relation between the copper base plate 31 at the bottom of the LED 30 and the copper pillar 20 can be achieved, and the high heat produced by the LED 30 can be conducted from the copper base plate 31 to the copper pillar 20, and then from the copper pillar 20 to the aluminum heat dissipating base plate 10. The high heat dissipating efficiency of the aluminum heat dissipating base plate 10 is provided for reducing the high temperature quickly to achieve the expected effect of reducing temperature. Since the aluminum heat dissipating base plate 10 further includes the flange 12 at the rim of the connecting hole 11, therefore the contact area between the copper pillar 20 and the aluminum heat dissipating base plate 10 becomes larger to enhance the heat conducting efficiency and the temperature reducing effects significantly.

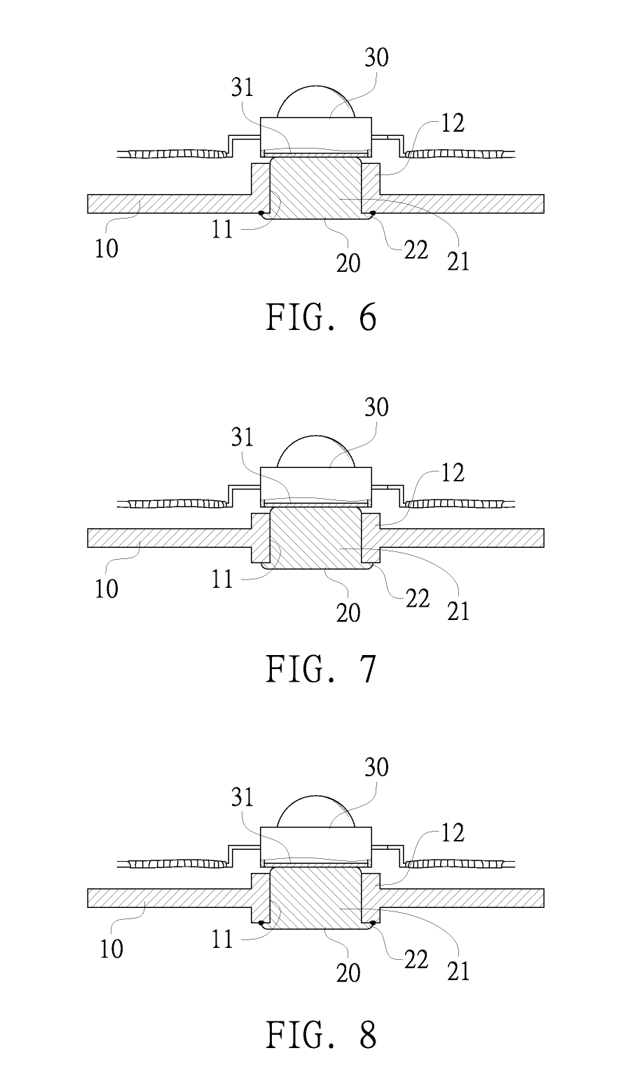

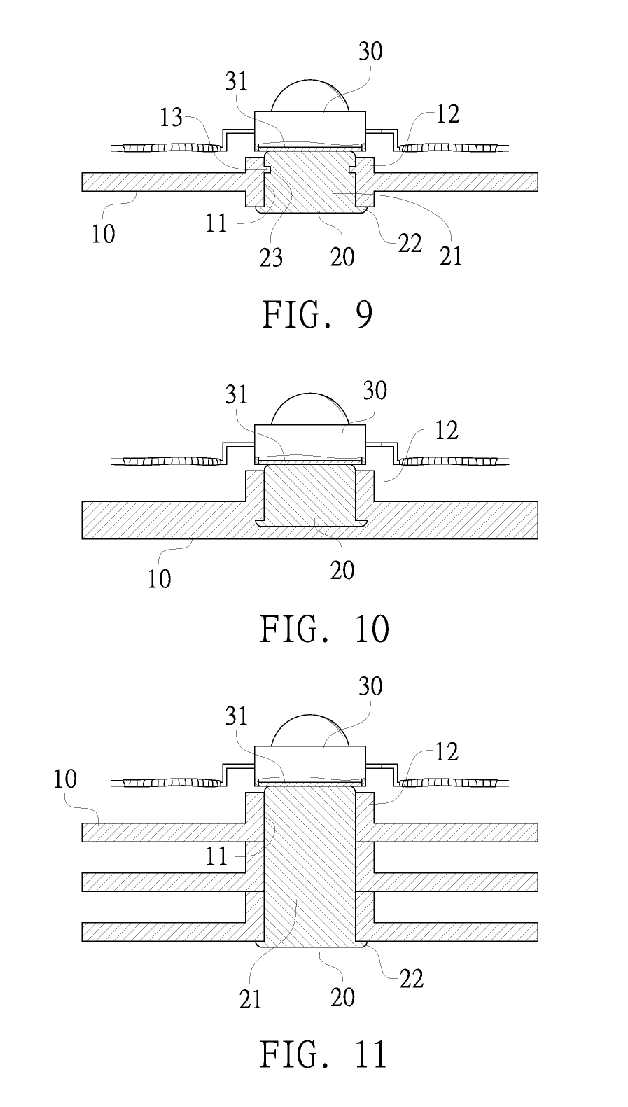

With reference to FIGS. 5 to 10 for preferred embodiments of combining the aluminum heat dissipating base plate 10 and the copper pillar 20 in accordance with the present invention, in addition to the aforementioned punch riveting method, the copper pillar 20 is sheathed into a pre-formed connecting hole 11 of the aluminum heat dissipating base plate 10, and the copper pillar 20 is fixed to the upper rim of the flange 12 of the aluminum heat dissipating base plate 10 or the lower rim of the connecting hole 11 by a soldering process to maintain the connecting relation of the copper pillar 20 and the aluminum heat dissipating base plate 10, such that the high heat produced by the LED 30 can be conducted through the copper pillar 20 to the aluminum heat dissipating base plate 10 for dissipating the heat and lowering the temperature (as shown in FIGS. 5 and 6), or the flange 12 is formed at upper and/or lower rim of the connecting hole 11 of the aluminum heat dissipating base plate 10, such that when the copper pillar 20 is installed into the connecting hole 11 by the punch riveting process, a larger contact area can be achieved to enhance the heat conducting efficiency significantly, and the copper pillar 20 and the aluminum heat dissipating base plate 10 can be soldered, to achieve a secured connection (as shown in FIGS. 7 and 8), or a circular protruding rib 13 is installed at a predetermined position of an internal rim of the connecting hole 11 of the aluminum heat dissipating base plate 10, and a circular embedding groove 23 is formed at a corresponding position of the body 11 of the copper pillar 20, such that when the copper pillar 20 is installed into the connecting hole 11 of the aluminum heat dissipating base plate 10, the circular protruding rib 13 can be embedded and latched into the circular embedding groove 23 for preventing the copper pillar 20 from falling out, so as to maintain the secured connection (as shown in FIG. 9). In addition, the aluminum heat dissipating base plate 10 can be manufactured by a plastic mold. Before the mold shaping takes place, the copper pillar 20 is installed at a predetermined position first, so that when the aluminum heat dissipating base plate 10 is formed, the copper pillar 20 is integrally coupled at the predetermined position to achieve a secured integrally formed structure (as shown in FIG. 10).

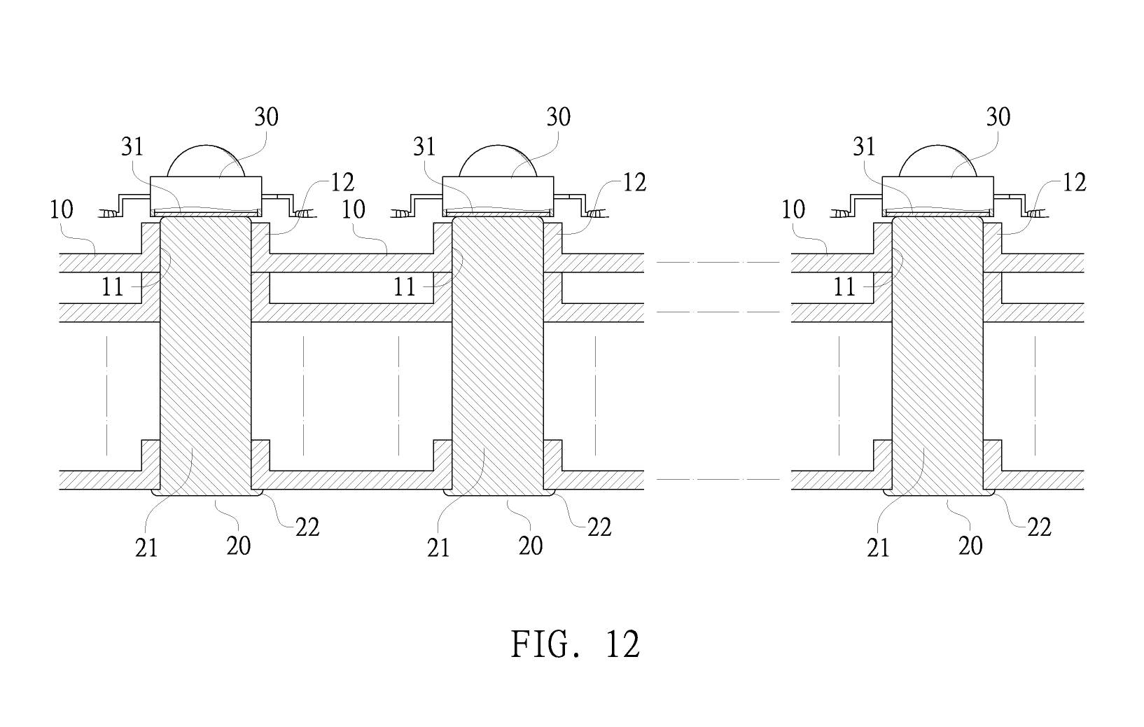

With reference to FIGS. 11 and 12 for schematic view of structural relations of the present invention, the design of the LED heat dissipating module makes use of the flange 12 formed at the rim of the connecting hole 11 of the aluminum heat dissipating base plate 10 to increase the contact area between the copper pillar 20 and the aluminum heat dissipating base plate 10 to enhance the heat conducting efficiency, and adopts one or more layers of aluminum heat dissipating base plates 10 (wherein the number of layers can be increased according to the actual requirements), and more than one connecting holes 11 are adopted as needed, and the flange 12 of the connecting hole 11 maintains an appropriate gap between two adjacent aluminum heat dissipating base plates 10, and the body 21 of the copper pillar 20 can be elongated, such that the copper pillar 20 can be passed and fixed to each connecting hole 11 at each layer of the aluminum heat dissipating base plates 10, and a distal end of the copper pillar 20 is exposed and protruded to touch the copper base plate 31 of the LED 30, such that the operating temperature of the LED 30 can be conducted to each layer of the aluminum heat dissipating base plates 10 through the copper pillar 20 to expedite the heat dissipating and temperature lowering effects.

In the aforementioned preferred embodiments of the present invention, aluminum heat dissipating base plate 10, an aluminum plate is connected to the aluminum heat dissipating base plate 10 at a position of each copper pillar 20 to cover the copper pillar 20 (not shown in the figure) to maintain the good external appearance.

In the structural design of the LED heat dissipating module of the present invention, the high thermal conductivity of copper and aluminum is used for achieving the high heat dissipating performance for lowering the operating temperature of the LED without increasing the thickness and material cost of the aluminum heat dissipating base plate, and the flange at the rim of the connecting hole is provided for increasing the of the contact area for the thermal conduction of the copper pillar, such that the heat conduction and the heat dissipation can be improved to achieve the effects of lowering the cost, improving the heat dissipation efficiency and extending the using life of the LED.

In summation of the above description, the present invention herein enhances the performance than the conventional structure and further complies with the patent application requirements and is duly submitted for patent application. While the invention is described in some detail hereinbelow with reference to certain illustrated embodiments, it is to be understood that there is no intent to limit it to those embodiments. On the contrary, the aim is to cover all modifications, alternatives and equivalents falling within the spirit and scope of the invention as defined by the appended claims.

What is claimed is:

1. A light emitting diode (LED) heat dissipating module, comprising: at least one layer of aluminum heat dissipating base plate, having at least one connecting hole formed thereon, and a flange formed around the rim of the connecting hole; and at least one copper pillar, tightly included in the connecting hole of the aluminum heat dissipating base plate, for coupling a copper bottom of a light emitting diode (LED) to a distal surface of the copper pillar.

2. The LED heat dissipating module of claim 1, wherein the connecting hole of the aluminum heat dissipating base plate includes a flange.

3. The LED heat dissipating module of claim 1, wherein the connecting hole and the copper pillar of the aluminum heat dissipating base plate separately have a quantity of more than one.

4. The LED heat dissipating module of claim 1, wherein the flange of the connecting hole of the aluminum heat dissipating base plate is disposed around an upper rim of the connecting hole.

5. The LED heat dissipating module of claim 1, wherein the flange of the connecting hole of the aluminum heat dissipating base plate is disposed around a lower rim of the connecting hole.

6. The LED heat dissipating module of claim 1, wherein the flange of the connecting hole of the aluminum heat dissipating base plate is separately disposed around upper and lower rims of the connecting hole.

7. The LED heat dissipating module of claim 1, wherein the connecting hole of the aluminum heat dissipating base plate includes a circular protruding rib installed around an internal rim of the connecting hole, and a body of the copper pillar includes an circular embedding rim disposed at a corresponding position for embedding and engaging the copper pillar into the circular protruding rib of the connecting hole.

8. The LED heat dissipating module of claim 1, wherein the aluminum heat dissipating base plate and the copper pillar are coupled by a punch riveting process.

9. The LED heat dissipating module of claim 1, wherein the aluminum heat dissipating base plate and the copper pillar are fixed by a soldering process.

10. The LED heat dissipating module of claim 1, wherein the aluminum heat dissipating base plate and the copper pillar are integrally coupled.

11. The LED heat dissipating module of claim 1, wherein the aluminum heat dissipating base plate has a quantity of more than one layer, and the body of the copper pillar has an elongated design, such that the copper pillar can be passed through each connecting hole formed on each layer of aluminum heat dissipating base plate.
